(19) United States
(12) Patent Application Publication
(10) Pub. No.: US 2008/0054938 A1
(43) Pub. Date: Mar. 6, 2008

(54) Microcontroller with low noise peripheral

(75) Inventors: Igor Wojewoda, Tempe, AZ (US); Ruan Lourens, Chandler, AZ (US)

Correspondence Address: BAKER BOTTS, LLP, 910 LOUISIANA, HOUSTON, TX, 77002-4995, US

(73) Assignee: Microchip Technology Incorporated

(21) Appl. No.: 11/460,854

(22) Filed: Jul. 28, 2006

(51) Int. Cl. H03K 19/173

(52) U.S. Cl. 326/38

(57) ABSTRACT

A microcontroller may have at least a first and second output port coupled with external first and second pins, respectively, a programmable switching arrangement operable in a first mode to provide for a first and second output signal at the first and second pins, respectively, and in a second mode to provide for a first output signal at the first pin and an inverted first output signal at the second pin.

### TECHNICAL FIELD

The technical field of the present application relates to microcontrollers.

### BACKGROUND

Microcontrollers typically comprise integrated on a single chip (Integrated circuit) a central processing unit (CPU), volatile and non-volatile memory, and a plurality of peripherals. Such a single chip is mounted in a housing having a plurality of external pins coupled with the internal circuits of the integrated circuit. The peripherals and other components of the microcontroller typically communicate with external components via these external contact pins. Thus, a plurality of digital signals can be fed from and to these external pins. FIG. 1 shows typical output driver circuitry 100 as used in many microcontrollers. Internal output signals 101a . . . 101n are fed to inputs of respective drivers 102a . . . 102n. The outputs of each driver 102a . . . 102n is coupled with an associated external connection pin 104n . . . 104n, respectively. Each driver 102a . . . 102n may also have an enablement input which is driven by a respective internal enablement signal 103a . . . 103n . A microcontroller may also have in addition input circuitry which operates in the reverse way of the shown output circuitry 100. Every integrated circuit will create electromagnetic noise when operated which can be measured and which depends on a plurality of parameters. In particular depending on the frequency of signals transferred through the external pins 104a . . . 104n, the overall noise created by an integrated circuit can significantly increase. Because the transferred signals are digital, they switch from either Vdd to Vss or vice versa, for example from 0V to 3.3V or 5V. These hard digital transitions will increase noise over a broad frequency band due to their characteristics.

Today, regulations for electromagnetic interference (EMI) and electromagnetic compatibility (EMC) are getting more and more stringent. Thus, in many areas specific maximum allowable radiation and emission levels are set which many microcontrollers due to their architecture cannot fulfill.

### SUMMARY

In one embodiment, a microcontroller may comprise at least a first and second output port coupled with external first and second pins, respectively, a programmable switching arrangement operable in a first mode to provide for a first and second output signal at the first and second pins, respectively, and in a second mode to provide for a first output signal at the first pin and an inverted first output signal at the second pin.

In another embodiment, a microcontroller may comprise at least a first and second input port coupled with external first and second pins, respectively, controllable first and second drivers coupled with the first and second pins, respectively for providing first and second input signals, and a controllable differential amplifier having two inputs coupled with the first and second pin and an output; wherein in a first mode the differential amplifier is disabled and in a second mode the first and second drivers are disabled and the differential amplifier is enabled.

In another embodiment, a microcontroller may comprise at least a first and second input/output port coupled with external first and second pins, respectively, a programmable switching arrangement operable in a first mode to provide for a first and second output signal at the first and second pins, respectively, and in a second mode to provide for a first output signal at the first pin and an inverted first output signal at the second pin, and controllable first and second input drivers coupled with the first and second pins, respectively for providing first and second input signals.

In another embodiment, a microcontroller may comprise at least a first and second input/output port coupled with external first and second pins, respectively, controllable first and second drivers coupled with the first and second pins, respectively for providing first and second input signals, a controllable differential amplifier having two inputs coupled with the first and second pin and an output; wherein in a first mode the differential amplifier is disabled and in a second mode the first and second drivers are disabled and the differential amplifier is enabled, and controllable third and fourth drivers coupled with the first and second pins for providing an output port function in a output mode.

Other technical advantages of the present disclosure will be readily apparent to one skilled in the art from the following figures, descriptions, and claims. Various embodiments of the present application obtain only a subset of the advantages set forth. No one advantage is critical to the embodiments.

### BRIEF DESCRIPTION OF THE DRAWINGS

A more complete understanding of the present disclosure and advantages thereof may be acquired by referring to the following description taken in conjunction with the accompanying drawings, in which like reference numbers indicate like features, and wherein:

FIG. 1 is a circuit diagram showing typical port drivers in a microcontroller;

FIG. 2 is a circuit diagram showing a first embodiment of port drivers according to the present application;

FIG. 3 is a circuit diagram showing a second embodiment of port drivers according to the present application;

FIG. 4 is a circuit diagram showing a third embodiment of port drivers according to the present application;

FIG. 5 shows a spectral frequency analysis of a microcontroller operating toggling a port with a first frequency; and

FIG. 6 shows spectral frequency analysis of microcontrollers operating toggling a port with a first frequency.

### DETAILED DESCRIPTION

As stated above, in one embodiment, a microcontroller may comprise at least a first and second output port coupled with external first and second pins, respectively, a programmable switching arrangement operable in a first mode to provide for independent first and second output signals at the first and second pins, respectively, and in a second mode to provide for a single output signal at the first and second pin wherein the second pin carries the inverted signal of the first pin.

The first and second pin can be driven by a respective first and second output driver. A first multiplexer can be provided which selects either the second output signal or the inverted first output signal as an input for the second output driver associated with the second pin. The first and second output drivers can be tri-state drivers controlled by an enable/disable signal. A microcontroller may further comprise a second multiplexer for providing a first or second enable/disable signal to the second output driver. The first and second pin can be arranged within a semiconductor housing next to each other. The enable/disable signals can be provided by a programmable register.

In one embodiment, a microcontroller may comprise at least a first and second input port coupled with external first and second pins, respectively, controllable first and second drivers coupled with the first and second pins, respectively for providing independent first and second input signals, and a controllable differential amplifier having two inputs coupled with the first and second pin and an output; wherein in a first mode the differential amplifier is disabled and in a second mode the first and second drivers are disabled and the differential amplifier is enabled.

The first and second drivers and the differential amplifier may comprise tri-state outputs and the output of the differential amplifier is coupled with the output of the first driver.

In one embodiment, a microcontroller may comprise at least a first and second input/output port coupled with external first and second pins, respectively, a programmable switching arrangement operable in a first mode to provide for independent first and second output signals at the first and second pins, respectively, and in a second mode to provide for a single output signal at the first and second pin wherein an inverted signal taken from the first pin is output at the second pin, and controllable first and second input drivers coupled with the first and second pins, respectively for providing first and second input signals.

Such a microcontroller may further comprise a controllable differential amplifier having two inputs coupled with the first and second pin and an output; wherein in a third mode the differential amplifier is disabled and in a fourth mode the first and second drivers are disabled and the differential amplifier is enabled. Such a microcontroller may also comprise a register for defining an operating mode of the input/output port. The first and second pin can be driven by a respective first and second output driver. A first multiplexer can be provided which selects either the second output signal or the inverted first output signal as an input for the second output driver associated with the second pin. The first and second output drivers can be tri-state drivers controlled by an enable/disable signal. A microcontroller may further comprise a second multiplexer for providing a first or second enable/disable signal to the second output driver. The first and second pins can be arranged within a semiconductor housing next to each other. The enable/disable signals can be provided by a programmable register.

In one embodiment, a microcontroller may comprise at least a first and second input/output port coupled with external first and second pins, respectively, controllable first and second drivers coupled with the first and second pins, respectively for providing independent first and second input signals, a controllable differential amplifier having two inputs coupled with the first and second pin and an output; wherein in a first mode the differential amplifier is disabled and in a second mode the first and second drivers are disabled and the differential amplifier is enabled, and controllable third and fourth drivers coupled with the first and second pins for providing an output port function in a output mode.

A microcontroller may further comprise a programmable switching arrangement operable in a third mode to provide for a first and second output signal at the first and second pins, respectively, and in a fourth mode to provide for a first output signal at the first pin and an inverted first output signal at the second pin.

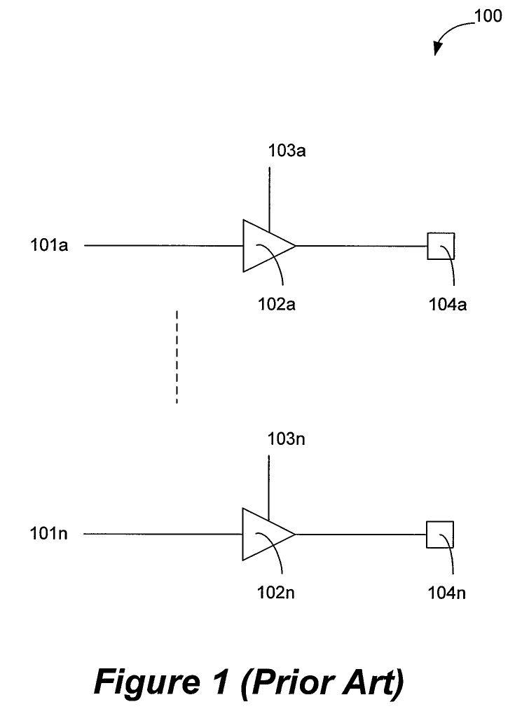

Turning to the drawings, exemplary embodiments of the present application will now be described. FIG. 1 depicts a first embodiment of an external output driver coupled with a microcontroller core 260. In this embodiment only two external pins 210 and 230 (output ports) are shown. However, a person skilled in the art will recognize that the depicted concept can be easily expanded to a plurality of output ports. Each output port 210, 230 has an associated output driver 205, 220 which comprises a data input and an enable input. The first output driver 205 receives at its data input an internal output signal 201 and at its enable input an internal enable signal 215 as known in the typical prior art output circuit. Thus, this first output port 210 operates as a typical output port once the enable signal 201 is activated.

A second output pin 230 is provided for a second output port. During normal operation, the associated output driver 220 receives an internal input signal 240 through a multiplexer 235 at its input port and forwards it to pin 230 if an internal enable signal 250 which is coupled with the enable input of driver 220 through a second multiplexer 245 during normal operation. The operation mode of the output circuit can be set in a dedicated register 255 within the microcontroller core 260 which provides for a control signal coupled with the first and second multiplexer 235 and 245. Thus during normal operation the first input of each multiplexer 235 and 245 is selected and the circuit operates exactly like the circuit shown in FIG. 1 providing for two independent output ports at the external pins 210 and 230.

In a low noise mode, however, only a single output port having two output pins 210 and 230 is provided. To this end, the second inputs of multiplexers 235 and 245 are coupled as follows. The enable signal 215 for driver 205 is also fed to the second input of multiplexer 245. The data signal 201 is inverted by inverter 225 and fed to the second input of multiplexer 235. Thus, when register 255 selects the second inputs of multiplexers 235 and 245, driver 220 associated with external pin 230 will be controlled by the same enable signal as driver 205 and will receive the same input signal, however inverted, as driver 205. Thus, external pins 210 and 230 now carry a symmetrical signal. This low noise mode is particularly useful if a high speed peripheral is connected to the microcontroller. Such a connection can now be provided by a balanced transmission line or twisted pair. A communication over such a balanced transmission line or twisted pair still radiates, however, through the inverted signal on the second line the radiation is effectively cancelled by the opposing phase. Thus, the asymmetry of a single port for a digital signal comprising either a logical 0 or 1 is cancelled by the 1:1 coupling.

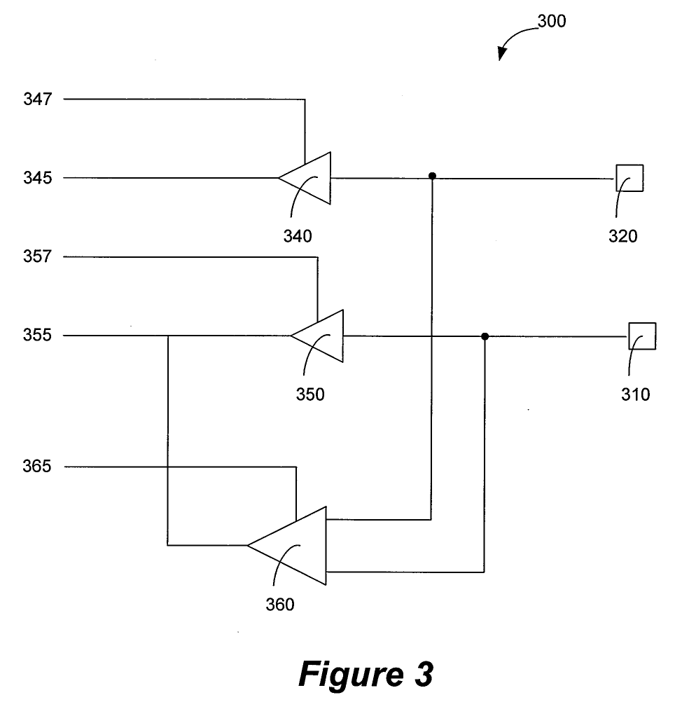

FIG. 3 shows another embodiment with an input driver circuit 200. Again, only two external pins 310, 320 are shown representing two input ports. In this embodiment, the first input pin 310 is coupled with the input of a first input driver 350 and input pin 320 with the input of a second driver 340. Each driver 350 and 340 also comprises an enable input receiving an internal enable signal 357 and 347, respectively from the microcontroller core (not shown in FIG. 3). The drivers 350 and 340 furthermore each comprise an output generating an associate internal input signal 355, 345, respectively. In addition, a differential amplifier 360 is provided. The differential amplifier 360 comprises an enable input receiving an internal enable signal 365 and two inputs which are coupled to the two input pins 310, 320, respectively. The output of differential amplifier 360 is coupled with the output of driver 350.

Drivers 340, 350, and differential amplifier 360 comprise tri-state outputs. Thus, during normal operation, the output of differential amplifier 360 is disabled through signal 365 and drivers 340 and 350 are enabled through signals 347 and 357. Thus, both pins 310 and 320 operate as separate input pins and the microcontroller has two input ports in this mode. However, in the second mode, only one input port is provided by the two pins 310 and 320. In this second mode, the drivers 340 and 350 are disabled through signals 347 and 357 and the differential amplifier 360 is enabled through signal 365. Thus, in this second mode, differential amplifier provides for an analysis of the signal difference between the signals that are fed to pins 310 and 320. Usually, logical input signals having states 1, 0 would lead to an output signal 355 having states 1, −1. Thus, differential amplifier preferably includes a conversion stage that converts this signal back to a logical signal having states 1, 0. Alternatively an extra output stage can be inserted between the output of differential amplifier 360 and the output of tri-state driver 350. This input driver circuitry 200 provides for the same benefits as explained above in conjunction with the output driver circuitry 100.

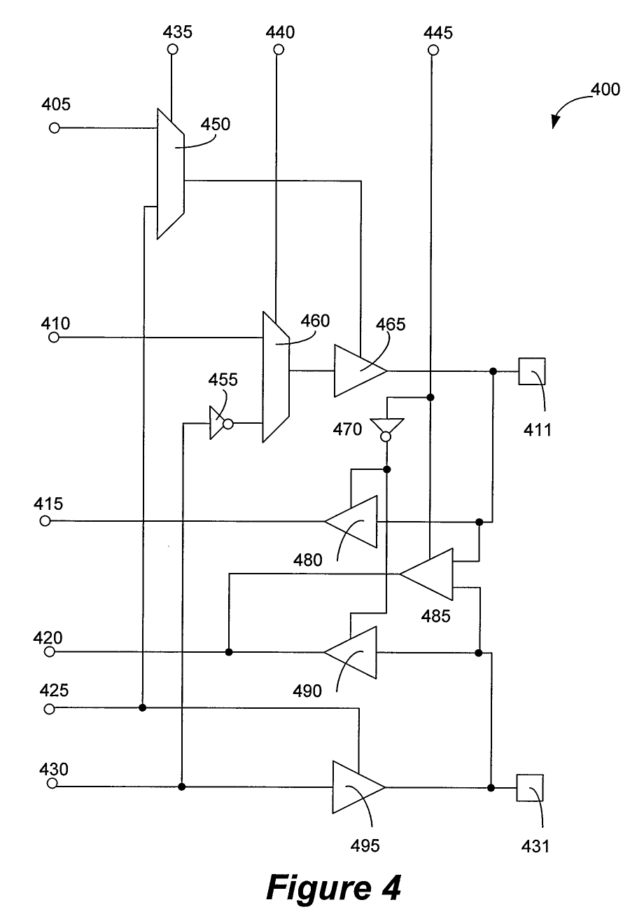

FIG. 4 shows a third embodiment of a combined input/output driver circuitry 400. Again, only two I/O pins 411 and 431 are shown. As explained above, the concept of all embodiments shown can be easily expanded to a plurality of pins. In the embodiment shown in FIG. 4, pins 411 and 431 can provide for either an input, an output, or a combined input/output function. A first output driver 495 is enabled/disabled by signal 425, receives internal output signal 430 and is coupled with its output to pin 431. A first input driver 490 is enabled/disabled by an output signal from an inverter 470, generates internal input signal 420 and is coupled via its input with pin 431. A second output driver 465 is enabled/disabled by the output signal of a first multiplexer 450, receives the output signal of a second multiplexer 460 and is coupled with its output to pin 411. A second input driver 480 is enabled/disabled by the output signal from inverter 470, generates internal input signal 415 and is coupled via its input with pin 411. A differential amplifier 485 is provided whose first input is coupled with pin 411 and whose second input is coupled with pin 431. Differential amplifier is designed similar as differential amplifier 360 shown in FIG. 3 and receives an enable signal 445 which is also fed to the input of inverter 470. The output of differential amplifier 485 is coupled with the output of the first input driver 490. The first multiplexer 450 comprises a first input receiving internal enable/disable signal 405 and a second input which receives internal enable/disable signal 425. Multiplexer 450 is controlled by internal control signal 435. The second multiplexer 460 receives internal output signal 410 at its first input and the output signal of inverter 455 whose input receives internal output signal 430. Multiplexer 460 is controlled by internal control signal 440.

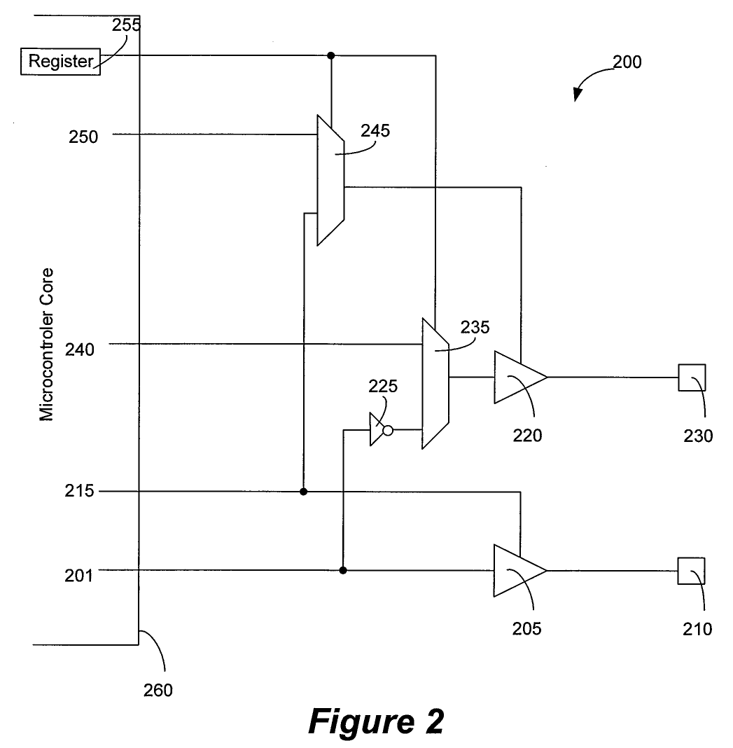

Some of the enable/disable signals for the internal drivers are generated from a signal control signal, for example using an inverter such as provided with internal control signal 445. However, all enable/disable signals as well as the control signals can be provided separately or can combined depending on the respective flexibility of the I/O circuit. These signals can be programmable through dedicated registers as for example shown in FIG. 2 or by other logic means. They can drive the respective drivers and/or differential amplifiers to provide for selective functionality such as, single input, balanced input, single output, balanced output, single input/output, or balanced input/output. Also, any type of combination of the embodiments disclosed can be made. In addition, a balanced/unbalanced output port as for example shown in FIG. 2 can be combined with a standard input port to provide for a combined I/O port. Similarly, a balanced/unbalanced input port as shown in FIG. 3 can be combined with a standard output port as shown in FIG. 1. In all embodiments, to be most effective, two pins providing for a balanced output are arranged within the semiconductor housing next to each other.

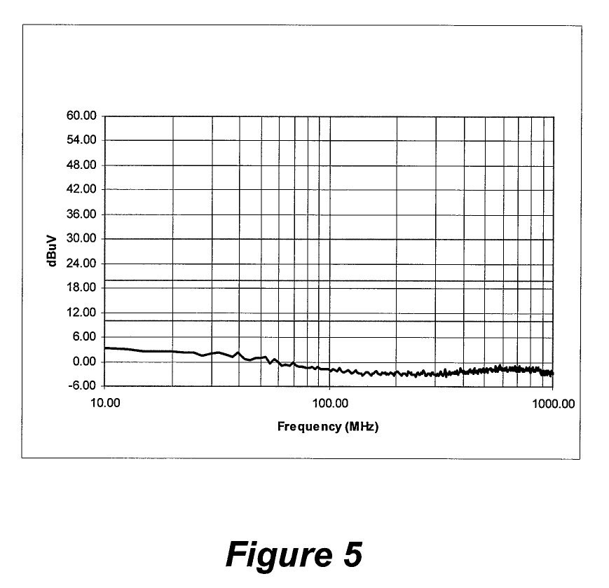

FIG. 5 shows as an example of a low noise microcontroller operating at 8 MHz. This microcontroller uses a normal port operation mode in which an output port is toggled at a frequency of 100 kHz. This exemplary microcontroller is designed to radiate almost no noise or very little noise. As can be seen, the noise level is below 3 dbμV. This microcontroller is designed in such a way that a low frequency toggling of a port does practically not introduce any spikes in the radiated frequency spectrum.

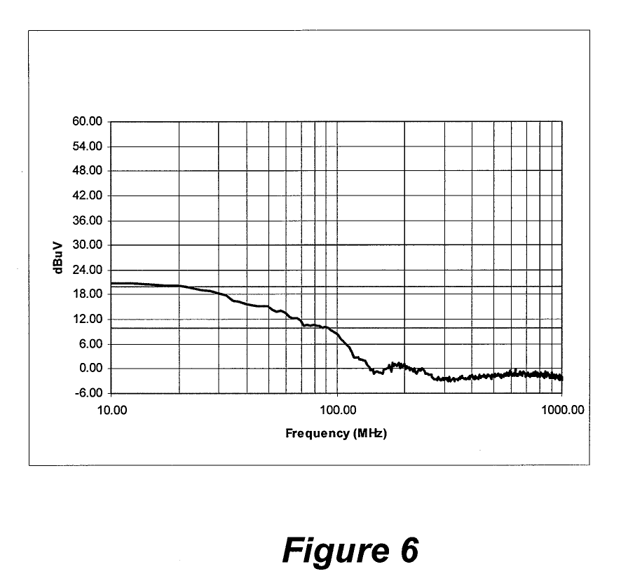

However, as shown in FIG. 6, the noise level drastically changes if the output toggling frequency is switched to a higher frequency. In FIG. 6, a frequency spectrum of the same low noise microcontroller is shown when a single output port is toggled at a frequency of 1 MHz. As can be seen, in the range of 10 MHz to approximately 100 MHz, the noise level raises by up to 18 dbμV. However, if such a the microcontroller uses one of the embodiments as disclosed above and the same port is operated in a second mode using a differential output signal then the radiated frequency spectrum will be maintained as shown in FIG. 5 even when high switching frequencies, such as for example, 1 MHz are used.

What is claimed is:

1. A microcontroller comprising:
at least a first and second output port coupled with external first and second pins, respectively;
a programmable switching arrangement operable in a first mode to provide for a first and second output signal at said first and second pins, respectively, and
in a second mode to provide for a first output signal at the first pin and an inverted first output signal at the second pin.

2. A microcontroller according to claim 1, wherein the first and second pin is driven by a respective first and second output driver.

3. A microcontroller according to claim 2, wherein a first multiplexer is provided which selects either the second output signal or the inverted first output signal as an input for the second output driver associated with the second pin.

4. A microcontroller according to claim 2, wherein the first and second output drivers are tri-state drivers controlled by an enable/disable signal.

5. A microcontroller according to claim 4, further comprising a second multiplexer for providing a first or second enable/disable signal to said second output driver.

6. A microcontroller according to claim 1, wherein said first and second pin are arranged within a semiconductor housing next to each other.

7. A microcontroller according to claim 2, wherein said enable/disable signals are provided by a programmable register.

8. A microcontroller comprising:
at least a first and second input port coupled with external first and second pins, respectively;
controllable first and second drivers coupled with said first and second pins, respectively for providing first and second input signals; and
a controllable differential amplifier having two inputs coupled with said first and second pin and an output; wherein in a first mode said differential amplifier is disabled and in a second mode said first and second drivers are disabled and said differential amplifier is enabled.

9. A microcontroller according to claim 8, wherein the first and second drivers and said differential amplifier comprise tri-state outputs and said output of said differential amplifier is coupled with the output of said first driver.

10. A microcontroller comprising:
at least a first and second input/output port coupled with external first and second pins, respectively;
a programmable switching arrangement operable in a first mode to provide for a first and second output signal at said first and second pins, respectively, and
in a second mode to provide for a first output signal at the first pin and an inverted first output signal at the second pin; and
controllable first and second input drivers coupled with said first and second pins, respectively for providing first and second input signals.

11. A microcontroller according to claim 10, further comprising:
a controllable differential amplifier having two inputs coupled with said first and second pin and an output; wherein in a third mode said differential amplifier is disabled and in a fourth mode said first and second drivers are disabled and said differential amplifier is enabled.

12. A microcontroller according to claim 10, further comprising a register for defining an operating mode of said input/output port.

13. A microcontroller according to claim 10, wherein the first and second pin is driven by a respective first and second output driver.

14. A microcontroller according to claim 13, wherein a first multiplexer is provided which selects either the second output signal or the inverted first output signal as an input for the second output driver associated with the second pin.

15. A microcontroller according to claim 13, wherein the first and second output drivers are tri-state drivers controlled by an enable/disable signal.

16. A microcontroller according to claim 15, further comprising a second multiplexer for providing a first or second enable/disable signal to said second output driver.

17. A microcontroller according to claim 10, wherein said first and second pins are arranged within a semiconductor housing next to each other.

18. A microcontroller according to claim 2, wherein said enable/disable signals are provided by a programmable register.

19. A microcontroller comprising:
at least a first and second input/output port coupled with external first and second pins, respectively;
controllable first and second drivers coupled with said first and second pins, respectively for providing first and second input signals;
a controllable differential amplifier having two inputs coupled with said first and second pin and an output; wherein in a first mode said differential amplifier is disabled and in a second mode said first and second drivers are disabled and said differential amplifier is enabled; and
controllable third and fourth drivers coupled with said first and second pins for providing an output port function in a output mode.

20. A microcontroller according to claim 19, further comprising:
a programmable switching arrangement operable in a third mode to provide for a first and second output signal at said first and second pins, respectively, and
in a fourth mode to provide for a first output signal at the first pin and an inverted first output signal at the second pin.
